(19) United States
(12) Patent Application Publication
(10) Pub. No.: US 2015/0125976 A1
(43) Pub. Date: May 7, 2015

(54) SELECTIVE SIDEWALL GROWTH OF SEMICONDUCTOR MATERIAL

(71) Applicant: NANOGAN LIMITED, Bath, Somerset (GB)

(72) Inventor: Wang Nang Wang, Bath (GB)

(21) Appl. No.: 14/406,194

(22) PCT Filed: Jun. 7, 2013
(86) PCT No.: PCT/GB2013/051502

§ 371 Date: Dec. 5, 2014

(30) Foreign Application Priority Data
Jun. 8, 2012 (GB) 1210134.1

(51) Int. Cl. H01L 21/02; H01S 5/022; H01L 31/18; H01L 21/308; H01L 33/00

(52) U.S. Cl. CPC H01L 21/0243; H01L 21/308; H01L 33/0095; H01L 31/186; H01S 5/02236; H01L 2933/0033
USPC 438/26; 438/498; 438/479; 438/64

(57) ABSTRACT

A method of producing a bulk semiconductor material comprises the steps of providing a base comprising a substantially planar substrate having a plurality of etched nano/micro-structures located thereon, each structure having an etched, substantially planar sidewall, wherein the plane of each said etched sidewall is arranged at an oblique angle to the substrate, and selectively growing the bulk semiconductor material onto the etched sidewall of each nano/micro-structure using an epitaxial growth process. A layered semiconductor device may be grown onto the bulk semiconductor material.

The present invention relates to methods of producing a bulk semiconductor material and methods of producing layered semiconductor devices.

The efficiency of optical devices such as light emitting diodes (LEDs) based on polar GaN falls off progressively as the wavelength or the current density is increased. The efficiency droop and the green gap in LEDs are two critical challenges facing the wider commercialization of solid-state lighting (SSL). Both have significant impact on the performance, and subsequently the cost, of SSL considering the lumens per watt ratio.

The relatively low internal quantum efficiency of green LEDs grown on conventional c-axis-orientated GaN arises partly from the slow rate of radiative recombination due to spontaneous and strain-induced piezoelectric polarisation. The strong polarisation field causes band bending in the InGaN quantum wells and subsequent spatial separation of electrons and holes distributions. This problem becomes more acute as the Indium content increases, i.e. towards longer working wavelengths, and is still present at the high carrier densities required for laser operation. Polarisation and Auger Recombination are also considered to be two of the major mechanisms responsible for the efficiency droop of LEDs grown on c-axis GaN. Further, foreign substrates, such as sapphire, SiC, Silicon, and (100) LiAlO₂, are commonly employed in nitride-based devices because of the lack of commercially available GaN substrates. The large lattice mismatch between III-Nitride epitaxy and such substrates causes a very high density of threading dislocations in state-of-the-art GaN-based devices (10⁸ to 10¹⁰ cm⁻² compared to ˜10⁴ cm⁻² of conventional AlGaAs-based devices). This further contributes to the limited efficiency, lifetime and optical output of currently available nitride-based visible sources.

There is growing evidence that these problems can be overcome by using non-polar and semi-polar orientations of GaN, for example (11-20) or a-plane GaN, or (10-10) or m-plane GaN, (20-21), (202-1), (20-2-1), (11-22), (10-1-1), and (10-1-3) or other semi-polar plane GaN. The absence and/or reduction of polarisation across the quantum wells leads to much higher gain and radiative recombination at lower carrier density and enables the use of wider wells for both LEDs and lasers.

In contrast, LEDs and laser diodes (LDs) fabricated on non-polar GaN grown directly on highly-mismatched foreign substrates have thus far been unsuccessful because of the high density of threading defects present. In the non-polar orientation, this problem is particularly acute owing to high densities of basal plane stacking faults that thread through the active layers. This high density of stacking faults and partial dislocations occur commonly in non-polar epitaxial GaN grown by existing methods.

ELOG and sidewall selective growth using micrometre-sized dielectric and metal masks have been used for the growth of high-quality non-polar and semi-polar GaN. Such methods reduce the density of stacking faults only by at best one order of magnitude, leaving their density still too high for efficient radiative recombination. There are additional complexities also, notably asymmetric wing tilts resulting from the different growth rates of the Ga-polar and N-polar wings which lead to new defects and strains at the coalescence boundaries. The threading dislocations and stacking faults which are less common in c-plane polar GaN are dominant because these defects are oriented nearly parallel to the c-plane GaN.

Non-polar and semi-polar growth methods are known from, for example: US-A1-2009/310640, US-A1-2007/218655 and US-A1-2010/102360. Other publications relating to such methods include:
1). Changqing Chen et al., “A New Selective Area Lateral Epitaxy Approach for Depositing a-Plane GaN over r-Plane Sapphire”. Jpn. J. Appl. Phys., 42, L818, 2003.
2). N. Okada, Y. Kawashima, and K. Tadatomo, “Direct Growth of m-plane GaN with Epitaxial Lateral Overgrowth from c-plane Sidewall of a-plane Sapphire”, Applied Physics Express 1, 111101 (2008).
3). K. Okuno, Y. Saito, S. Boyama, N. Nakada, S. Nitta, R. G. Tohmon, Y. Ushida, and N. Shibata, “m-Plane GaN Films Grown on Patterned a-Plane Sapphire Substrates with 3-inch Diameter,” Applied Physics Express, 2, 031002, 2009.
4). T. Tanikawa, T. Hikosaka, Y. Honda, M. Yamaguchi, and N. Sawaki, “Growth of semi-polar (11-22) GaN on a (113) Si substrate by selective MOVPE”, phys. stat. sol. (c) 5, No. 9, 2966-2968 (2008).
5). T. Tanikawa, D. Rudolph, T. Hikosaka, Y. Honda, M. Yamaguchi, N. Sawaki “Growth of non-polar (11-20) GaN on a patterned (110) Si substrate by selective MOVPE”, Journal of Crystal Growth 310, 4999-5002 (2006).
6). P. de. Mierry, N. Kriouche, M. Nemoz, S. Chenot, and G. Nataf, “Semipolar GaN films on patterned r-plane sapphire obtained by wet chemical etching”, Appl. Phys. Lett, 96, 231918 (2010).
7). N. Okada, A. Kurisu, K. Murakami, and K. Tadatomo, “Growth of semipolar (11-22) GaN layer by controlling anisotropic growth rates in r-plane patterned sapphire substrate”, Appl. Phys. Express, 2, 091001 (2009).

It is an aim of the present invention to overcome the above problems, and provide a method of growing non-polar and semi-polar high-quality materials and devices, which exhibit both low stress and low defect density.

In accordance with the present invention, this aim is achieved by using etching at an oblique angle to fabricate nano/micro-structures possessing at least one inclined sidewall, and then selectively growing semiconductor material from a portion of the inclined sidewalls.

For the avoidance of doubt, the term nano/micro-structure as used herein is taken to mean a nano-structure, a micro-structure or a combined nano/micro structure, i.e. a structure having a width (being the smallest dimension in a direction parallel to the structure's substrate) in the range from 1 nm to 999 nm (0.999 μm).

A semiconductor-material growth method, making use of oblique-angle nanostructures, is known from GB-A-2460898. However, in that document, semiconductor overgrowth is initiated from the tips of the nanostructures only amongst other differences, the present invention recognises that improvements may result from using selective growth from the inclined sidewalls themselves.

There are various advantages of sidewall lateral growth using oblique-angle etched templates, for example:
a) The oblique-faceted nano/micro-structure, which may be maskless or capped by metal/dielectrics mask material, can create the sidewall of a desired crystal orientation for controlled growth;
b) The combination of nanometre air gap and etched structure restricts lateral overgrowth only on the +C orientation sidewall of the etched structure, with fast coalescence due to the nanometre-sized air gap;
c) If the etched nano/micro-structures are themselves orientated at an oblique-angle to the substrate (here, oblique-angle etching means that the etching angle is tuned between zero and ninety degree relative to the surface of the etching target), the overgrown thick semiconductor materials or devices from the etched sidewall may be separated from the substrate by simply applying a pressure through the top surface, e.g. by pressing down on the material or device, which creates a tensile stress for the oblique-angle etched structure. This type of pressure is compatible with a wafer bonding technique. This characteristic is unobtainable using known structures with a vertical configuration, with which separation of the top-grown materials and devices cannot be achieved by simply applying the pressure from the top, as this only increases the compressive strain. Under compressive condition, a much larger force is required to reach the breaking point. In contrast, using oblique-angle etched nano/micro-structures, the pressure from the top increases the tensile stress because of the angle, therefore the top-grown materials and devices can be separated with much less force; and
d) The nanometre-sized etched structure facilitates the termination of partial dislocations and stacking faults through the fast growth of GaN on c-plane and c-plane-like sidewalls through the tuning of temperature, pressure and V/III ratio using MOCVD.

In accordance with a first aspect of the present invention there is provided a method of producing a semiconductor material as set out in the accompanying claims.

In accordance with a second aspect of the present invention there is provided a method of producing a layered semiconductor device as set out in the accompanying claims.

The top of the structure may be capped by mask materials or alternatively with the mask materials removed. At least one of the etched sidewalls is oriented obliquely upwards with +C-like direction to promote Ga-polar growth.

The characteristics of the nano/micro-structure arrangement are preferably as follows:

The structures are preferably separated by air gaps in the range of a few nanometres to less than 1000 nanometres, and the width of the top terrace of the etched structure, i.e. a substantially planar terrace, substantially parallel to the plane of the substrate, is also preferred to be in the range of a few nanometres to less than 1000 nanometres, or in an alternative configuration, in the range from 5 to 15 μm.

The etched depth of the nano/micro-structures (i.e. the height of the nano/micro-structures in the direction extending from the substrate) may be in the range from about a few hundred nanometres to ten micrometres. A preferred etched depth range is 100-120 nm.

The ratio of the etched depth to the width of the etched nano/micro-structures is preferably larger than one. Preferably, the minimum thickness of the etched nano/micro-structures is from about 10 nm-10,000 nm. Each nano/micro-structure preferably has a length in a direction parallel to the plane of the substrate which lies in the range from 1 μm to the full extent of the substrate.

Preferably, at least one etched sidewall comprises a plane which is c-plane-like. In the case of sapphire for example, a c-plane (001) or close to this crystal orientation is preferred. In the case of Si, the plane orientation is (1-11) or close to this crystal orientation. The requirement for these types of planes is that they favour the fast growth of Ga-polar facet GaN. Preferably, at least one etched sidewalls comprises a plane which is −c-plane-like. In the case of sapphire, a −c-plane (00-1) or close to this crystal orientation is preferred. In the case of Si, the plane orientation is (−11-1) or close to this crystal orientation. The requirement for these type of planes is that they have very slow growth of GaN, i.e. much slower than for the c-plane-like sidewall. These sidewalls could be oriented between zero and ninety degrees from the plane of the substrate surface or alternatively nearly parallel to each other.

The following sidewall selective growth along the c-plane and c-plane-like sidewalls of non-polar and semi-polar GaN can be carried out to achieve reduced defects and stacking faults. This defects reduction and termination mechanism is achieved mainly as a result of the nanometre-sized air gaps and etched structures. The fast growth of Ga-polar GaN along the c-axis is carried out with very fast growth, so that the lateral grown GaN can quickly extend over the adjacent air gap because of nanometre-sized air gap and etched structures. The sideway extended stacking faults and dislocations grown out of the hetero-interface are blocked by the fast grown GaN.

The width of the air gap for C-plane Ga polar growth is controlled in the nanometre scale to restrict growth from the bottom of the etched structure through limited mass transport. The nanometre-sized etched structure facilitates the defects annihilation and stacking faults reduction by quick coalescence in the lateral overgrowth over the structure.

Preferably, the substrate material is selected from the group consisting of sapphire, silicon, diamond, metal oxides, and compound semiconductors. These include sapphire (γ-plane, a-plane, m-plane, (22-43), or different off-axis on these wafers), SiC (6H, 3H, 3C, m-plane etc), Si ((100), (110), (113), or different off-axis on these wafers), ZnO, GaN ((11-22), (10-11), (20-21), (10-10), (11-20), or different off-axis on these wafers), AlN, AlGaN, GaAs, LiAlO₂, NdGaO₃ etc. For the growth of non-polar materials such as a-plane or m-plane GaN, the crystal orientation of the substrate can be γ-plane sapphire or m-plane 4H- or 6H-SiC respectively. For the growth of semi-polar materials such as (11-22) GaN, the crystal orientation of the substrate can be (113) Si with the etched stripes along [21-1] of sidewalls along (1-11) and (−11-1). For the growth of semi-polar materials such as (11-22) GaN, γ-plane sapphire can also be used, with the etched stripe along the [11-20] direction of the γ-plane sapphire.

The substrate material may also be selected from the group consisting of conductive substrates, insulating substrates and semi-conducting substrates.

The nano-structures may be fabricated by etching, including at least some etching at an oblique angle, directly to a substrate or a template with a semiconductor layer which may be grown by molecular beam epitaxy (MBE), metalorganic chemical vapour deposition (MOCVD) (such as metalorganic vapour phase epitaxy (MOVPE)), reactive sputtering, hydride vapour phase epitaxy (HYPE), or any other semiconductor growth methods onto a substrate. The template can be made of a simple layer, or of a heterostructure. The total thickness of the above mentioned semiconductor layer is preferably less than 3 μm.

Such an etching process involves forming a mask onto the template to control the dimensions of the nano-structures produced. The mask can be produced for example by interferometry, holography, e-beam lithography, photolithography, nano-imprint technology, or any other mask making technologies.

Nano-imprint nano-mask fabrication processes involve:
(a) depositing dielectric materials and or metals onto the substrate or the template consisting of the substrate and the deposited semiconductor material;
(b) coating the surface with photon-curable or thermal curable pre-polymers;
(c) nano-imprinting the nano-mask pattern onto the pre-polymers;
(d) curing the pre-polymers to form a cured polymer patterns;
(e) dry, wet or combined dry and wet etching the cured polymers and dielectric materials using the patterned nano-masks;
(f) dry, wet, or combined dry and wet etching the substrate or semiconductor materials using the polymer and dielectric/metal nano-masks to form a high density of oblique-angle nano-structures with the residue dielectric materials and or metals still capped or removed.

The nano-structures may be fabricated by dry-etching with the substrate tilting at an oblique angle towards the incoming ion beams or plasma, i.e. at an angle between 0 and 90 degrees, (0°<tilt angle of the substrate<90°). The aspect ratio (i.e. height versus width) of the etched nano-structures is preferably set to be larger than one for the nanometre sized air gap and terrace. For the nanometre sized air gap and micrometre sized terrace, the height is compatible with the width of the air gap in the few tens to few hundreds nanometre range. Dry-etching of the semiconductor layers may be carried out by ion beam etching, reactive ion etching (RIE), inductively coupled plasma etching (ICP), or ion beam etching using Ar, CHF₃, Cl₂, BCl₃ or H₂ gas mixtures. An alternative technique for the fabrication of oblique-angle etched structures is to use a combination of dry etching and wet etching with the substrate mounted with the surface perpendicular to the incoming ion beams and plasmas. In the case of γ-sapphire, the dry etching may be carried out by ICP etching using Ar, Cl₂, and BCl₃, followed by wet etching using H₃PO₄:H₂SO₄=3:1 solution at 270° C. for about 1 to 10 minutes. The substrate is mounted in a normal position during the dry etching to form the nearly vertical sidewalls. After the selective wet etching, at least one of the etched sidewalls contains (0001) and (1-100)-like sapphire plane. At least one of the etched sidewalls forms a clearly inclined angle to the substrate surface plane. At least one of the etched sidewalls consists of a c-plane or c-plane-like sapphire plane to facilitate the fast Ga-polar GaN growth. In the case of (113) Si, the dry etching may be carried out by ICP etching using Ar, CHF₃, and H₂, followed by wet etching using KOH (25 wt %) at 40° C. for 1 to 5 minutes. The etched sidewalls contain a (1-11) and (−11-1)-like Si plane. The dry etching process can alternatively be carried out in plasma-less etching using CIF₃, BrF₃, BrF₅, or IF₅. Using this combined dry and wet etching, the mask caps are usually wider than the etched terrace due to the undercutting etching in the wet etching process.

A dielectric material such as SiO₂ or Si₃N₄, which can be deposited by sputtering, e-beam evaporation or plasma-enhanced chemical vapour deposition (PECVD), may serve as the mask with the replicated pattern from the nano-masks produced by the above-mentioned technologies. The thickness of the dielectric layer depends on the etching selectivity between the dielectric materials and the semiconductor layers to be etched. A metal material such as Ni, Mo, W, Ti, or a rare earth metal material can be deposited in the same manner. The metal can also be further annealed with reactive gases to form metal oxides or metal nitride mask materials.

The nano-structures produced can have various configurations, for example nano-pillars or air nano-pores surrounded by continuous nano-networks of any desired patterns. The nano-structures may have different shapes such as square, rectangular, triangular, trapezoidal, or other polygons. The nano-structures can have composite patterns of divided pixels containing the nano-structures. These pixels can have a range of different shapes and sizes, which range from few micrometers to few millimetres. The dimensions of the nano-structures can be modified by further wet-etching using various acids and bases. Such treatment allows the fine tuning of the diameter of the nano-structures for optimized lateral overgrowth and ready separation of such grown thick, free-standing, compound semiconductor materials from the substrate. The wet-etching can also etch under the mask material, i.e. partially removing template material underlying the mask, and then create a region of overhanging mask cap such that each terrace carries a region of mask cap that is of greater width than the respective terrace. This overhanging mask can reduce the defect density during subsequent selective sidewall lateral overgrowth. Where capping masks are retained on top of the etched nano/micro-structures, with the mask material extended over the etched nano/micro-structures, the width of the mask caps is wider than that of the terrace due to undercutting etching of the template which generally happens using wet-etching to etch the template materials.

Selective etching by wet-etching can also create a better sidewall to facilitate +C plane Ga-polar growth. An extra passivation using oxides, nitrides or metal alloys can be selectively deposited and etched to block the non-c-plane facet and expose the c-plane and c-plane-like sidewall for selective growth of GaN.

The quality of the etched nano/micro-structures can be improved by annealing the composite structure at different selected temperatures and under different ambient gases. Suitable annealing temperatures range from about 200 to 1200° C. under Ar, He, H₂, N₂, NH₃, or other suitable gases or gas mixtures. The bottom, −C plane, of the etched nano-structures can alternatively or additionally be passivated with in-situ or ex-situ oxidation and/or nitridation processes.

Fabricated nano-structure templates can be loaded for initial thin continuous GaN epitaxial lateral overgrowth (ELOG) using MBE, MOCVD or HVPE. Thus-prepared templates can then be loaded for subsequent thick semiconductor material growth using HVPE, and subsequent full device epitaxial growth using MOCVD, MBE or HVPE.

The single-crystal semiconductor material may comprise a different material from the nano-structures.

The single-crystal semiconductor material may comprise different alloys.

The semiconductor material may be undoped, or n- or p-type doped.

The grown semiconductor material may be separated from the substrate for example by mechanically cracking the relatively weak nano-structures, or by wet etching, photochemical etching, electrochemical etching, or by laser ablation.

The semiconductor material thus grown may go through slicing, lapping, and/or polishing processes to be epitaxially ready for further device growth, or may be used as the seed material for the further growth of thick semiconductor material with lower defect density.

The semiconductor devices produced by the method are preferably epitaxially grown. This growth may be carried out by various methods, for example HVPE, MOCVD (MOVPE), CVD, sputtering, sublimation, or an MBE method, or by selectively combining HVPE, MOCVD (MOVPE), CVD, sputtering, sublimation, and MBE methods.

The epitaxially-grown devices may consist of undoped, n- or p-type doped materials.

The epitaxial growth may be partially conducted using a pulsed growth method.

Advantageously, the growth of the devices is performed while rotating the substrate.

The grown compound semiconductor devices may be separated from the substrate after the p-side of the device has been bonded to a thermal expansion coefficient-matched sub-mount wafer. The separation can be done for example by mechanically cracking the relatively weak nano-structures, or by wet-etching, photochemical etching, electrochemical etching, or by laser ablation.

A mask design with controlled air gap between the nano/micro-structures allows a large confinement and deflection of defects with initial growth from the sidewall of narrow air gap. The controlled, fast vertical growth along the c-axis of the inclined sidewall over the nm-sized terrace terminates nearly all defects parallel to the c-plane grown from the next air gap. The use of deep-etched oblique-angle nano/micro-structures allows the overgrown LED and LD devices to be cleanly separated from the substrate for high performance thin GaN vertical devices. The simple wafer-bonding process will generate enough tensile strain to break the oblique-angle etched nano/micro-structures. This potential recycling use of the substrate opens the possibility for high performance AlGaN-free LD and maximized micro-cavity effects for vertical thin GaN devices, particularly for GaN on Si.

The initial substrates can be of different crystal orientations, for example: γ-plane sapphire, m-plane sapphire, m-plane 4H and 6-H SiC, (100) Si, (112) Si, (110) Si, and (113) Si. The crystal may have off-axis of few tenths of a degree to a few degrees.

The growth processes provided by the present invention can be applied to the family of III-V nitride compounds, generally of the formula InₓGa_{y}Al_{1-x-y}N, where 0≦x≦1, 0≦y≦1, and 0≦x+y≦1, or other suitable semiconducting nitrides.

Throughout the following description, the present invention is described using GaN as an example of an epitaxial III-V nitride layer as the semiconductor material for convenience, though any suitable semiconducting material may be used.

A device grown from the Ga-polar sidewall of the nano/micro-structures can be fabricated and packaged with the substrate attached. Alternatively, such a device may be fabricated and packaged with the substrate removed. The separation of the grown device can be achieved for example by various methods. In brittle materials such as sapphire and III-V nitrides, cracking may occur easily if the stress exceeds a critical value. Using oblique-angle etched III-nitrides nano/micro-structures with controlled aspect ratio and nano-dimensions facilitates cracking between the substrate and the top device during the wafer bonding process. Other methods such as chemical etching using KOH, oxalic acid or phosphoric acid etc, or photochemical etching combining wet chemical etching and UV light are all suitable for separating the device from the substrate. Laser ablation can also be used to separate the devices via from the substrate. The separation can also be conducted with a combination of the above-mentioned methods.

Specific embodiments of the invention will now be described with reference to the accompanying drawings, in which:

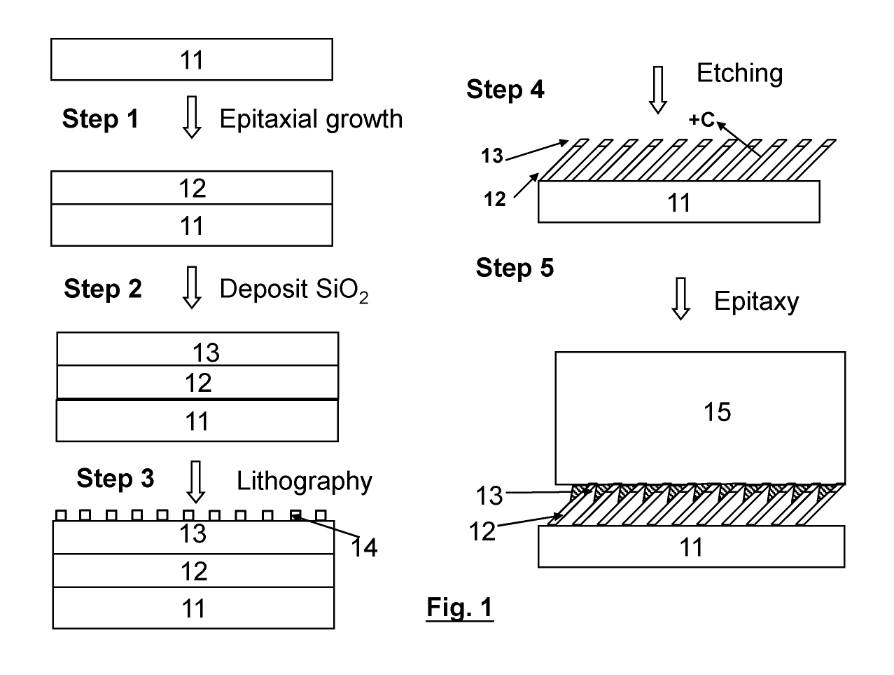

FIG. 1 schematically shows the process flow of a first embodiment of the present invention, for the fabrication of nano/micro-structures in the form of oblique-angle etched nano-stripes with capped mask material and the sidewall selective epitaxy lateral growth of n-polar and semi-polar semiconductor materials;

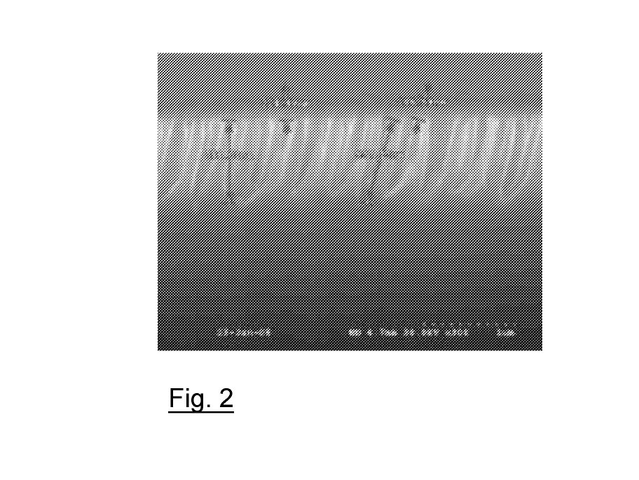

FIG. 2 shows an SEM cross-sectional view of GaN nano-structures formed in accordance with the first embodiment;

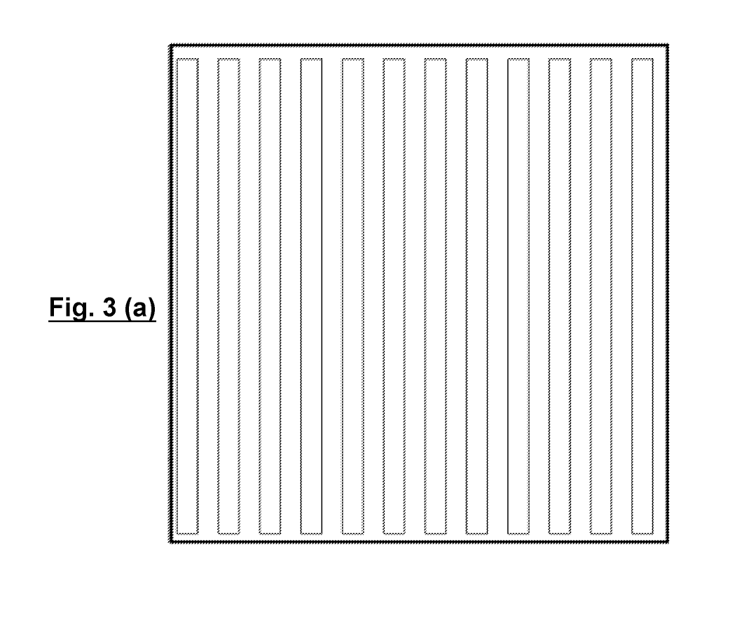

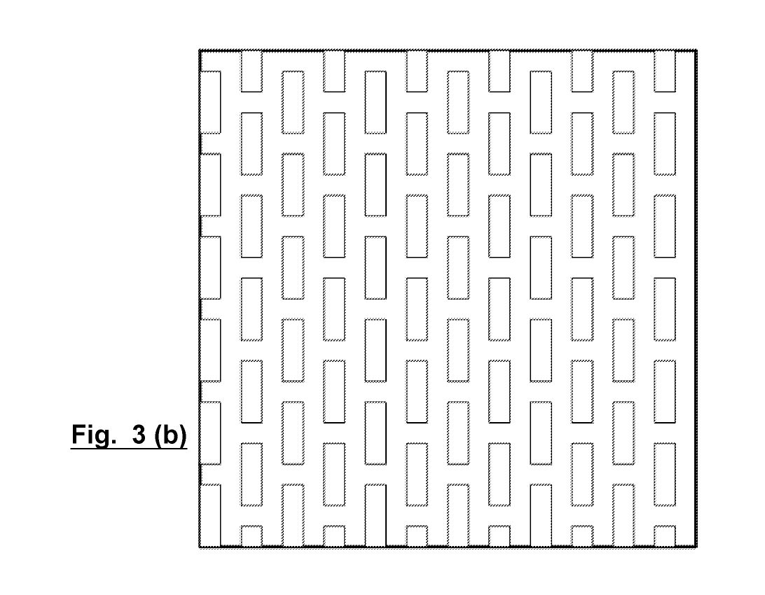

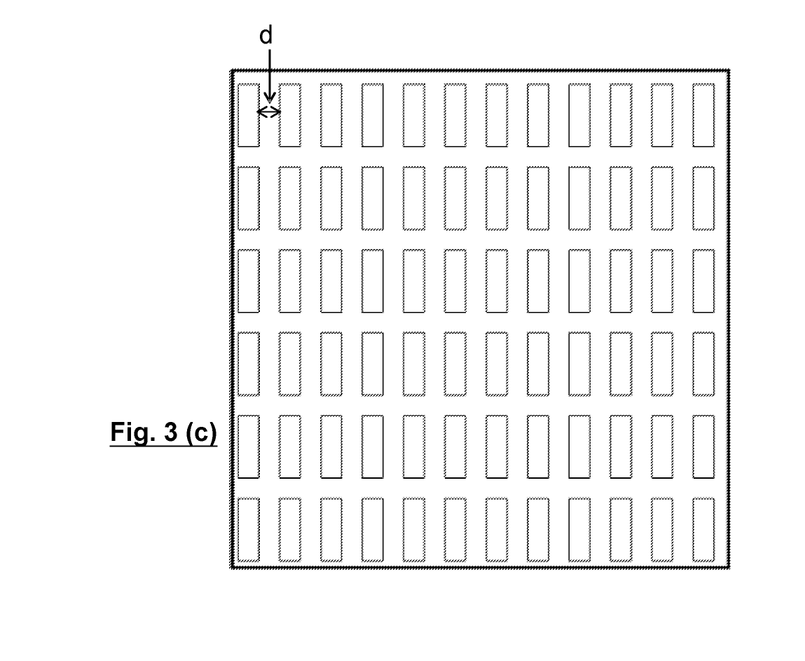

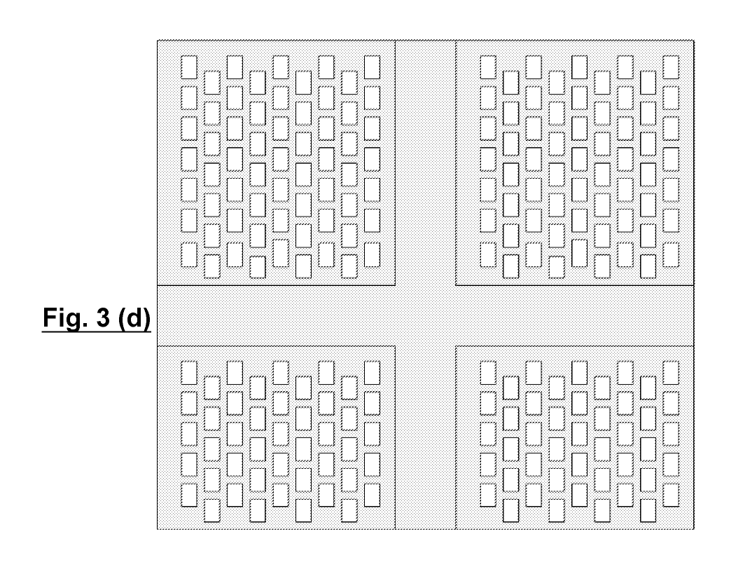

FIGS. 3a-d schematically show planar views of various nano/micro-structure mask patterns in accordance with the present invention;

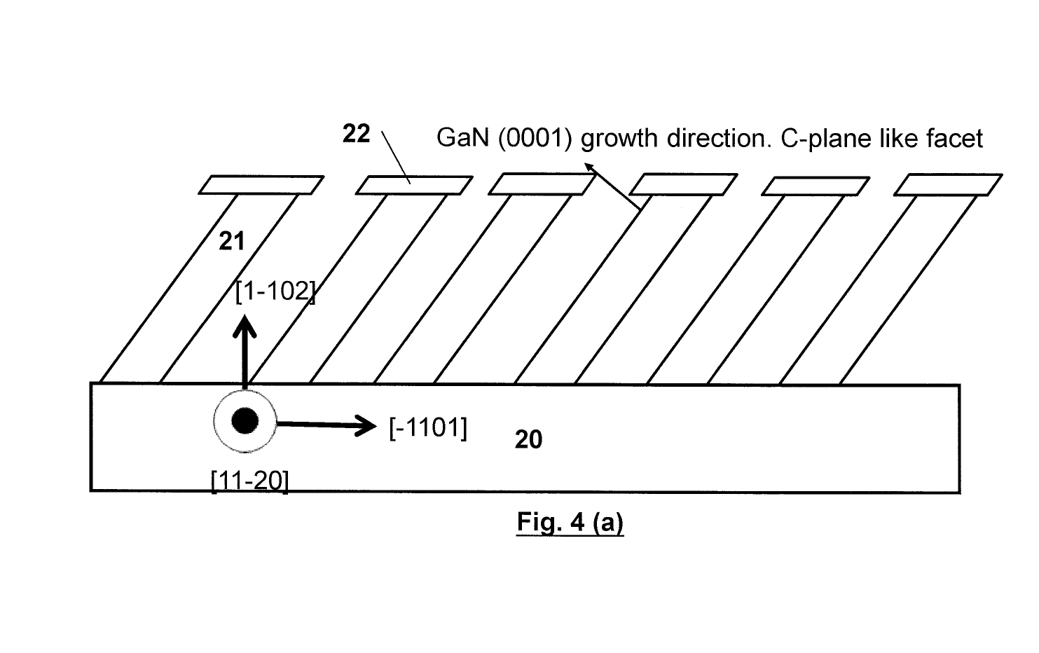

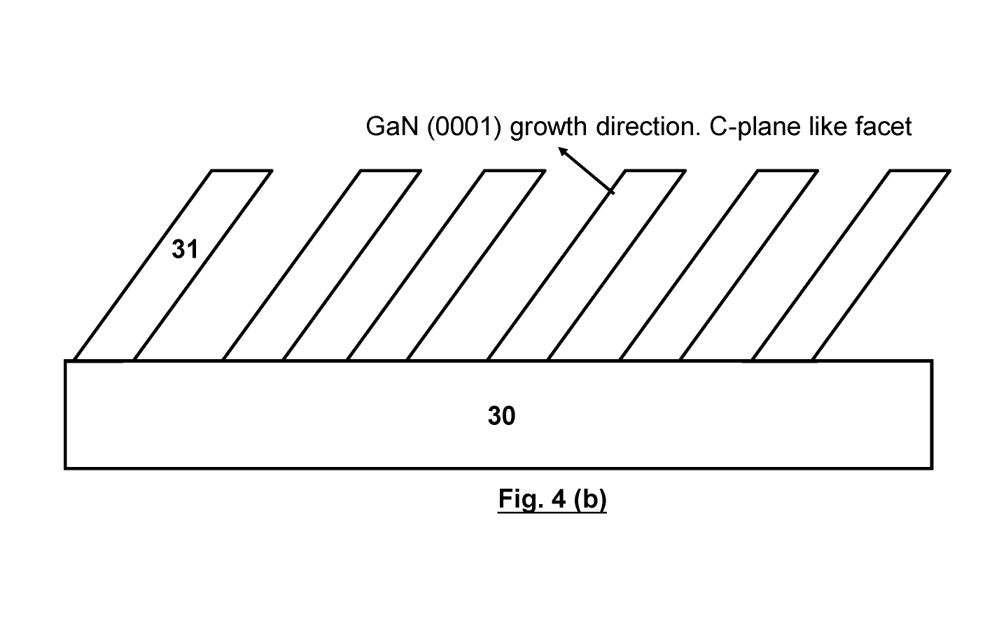

FIGS. 4a, b schematically show etched oblique-angled nano/micro-structures with mask on and mask removed respectively, both in accordance with the present invention;

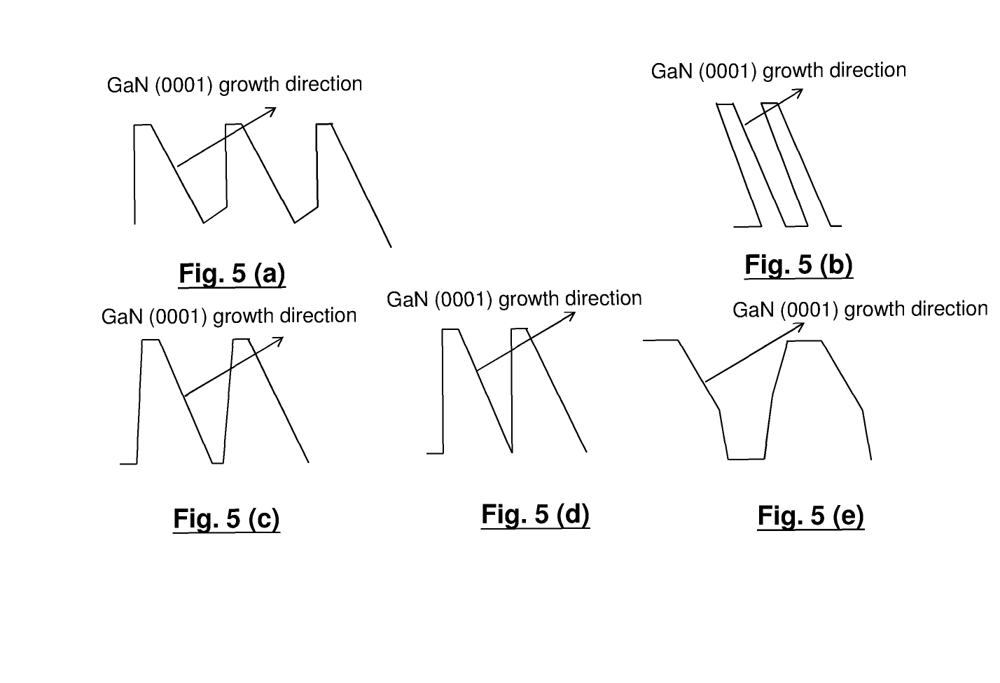

FIGS. 5a-e schematically show possible shapes of nano/micro-structure in accordance with the present invention;

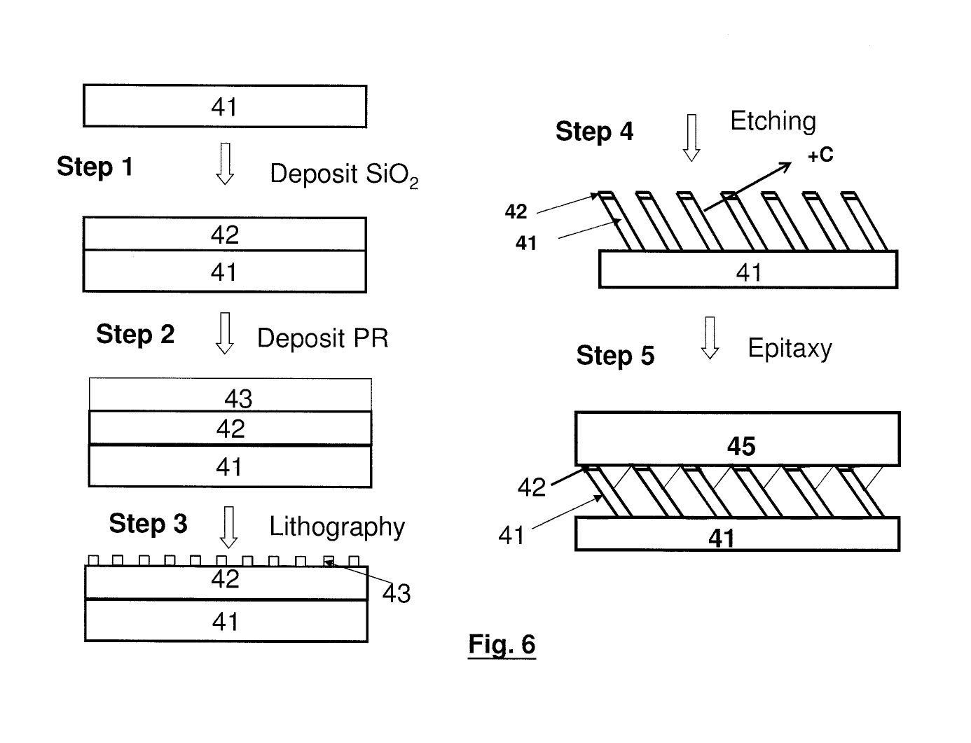

FIG. 6 schematically shows a process flow for the fabrication of oblique-angle etched nano-stripes with capped mask material and the sidewall selective epitaxy lateral growth semiconductor materials in accordance with a further embodiment of the present invention;

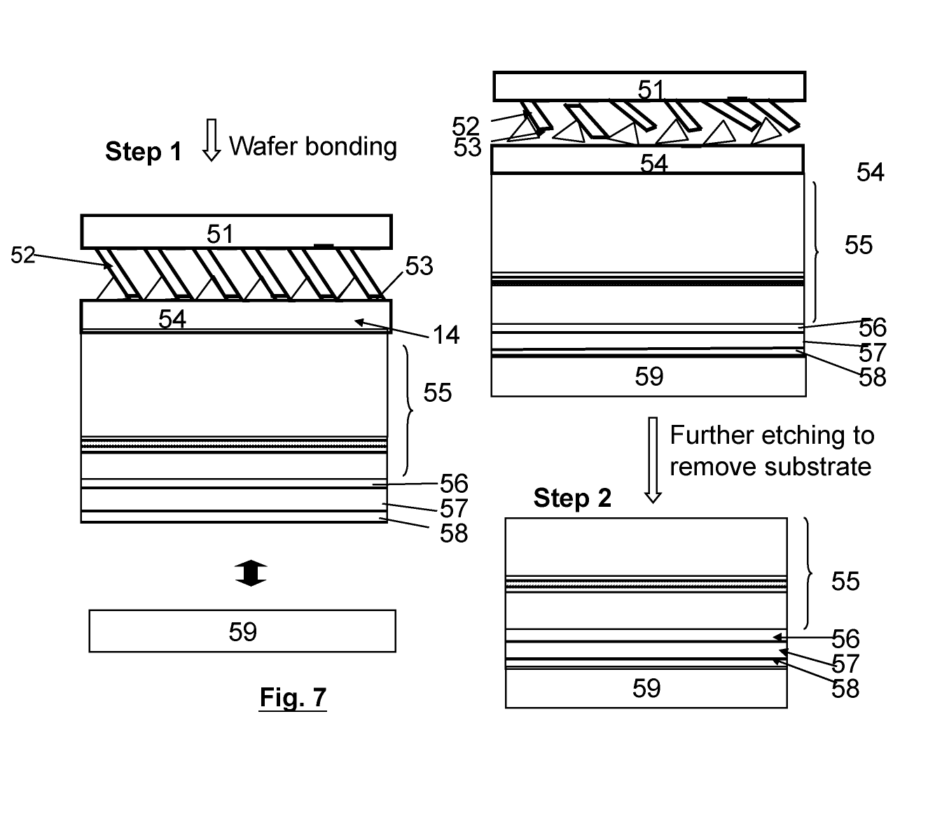

FIG. 7 schematically shows a wafer bonding process for the fabrication of an LED device in accordance with the present invention;

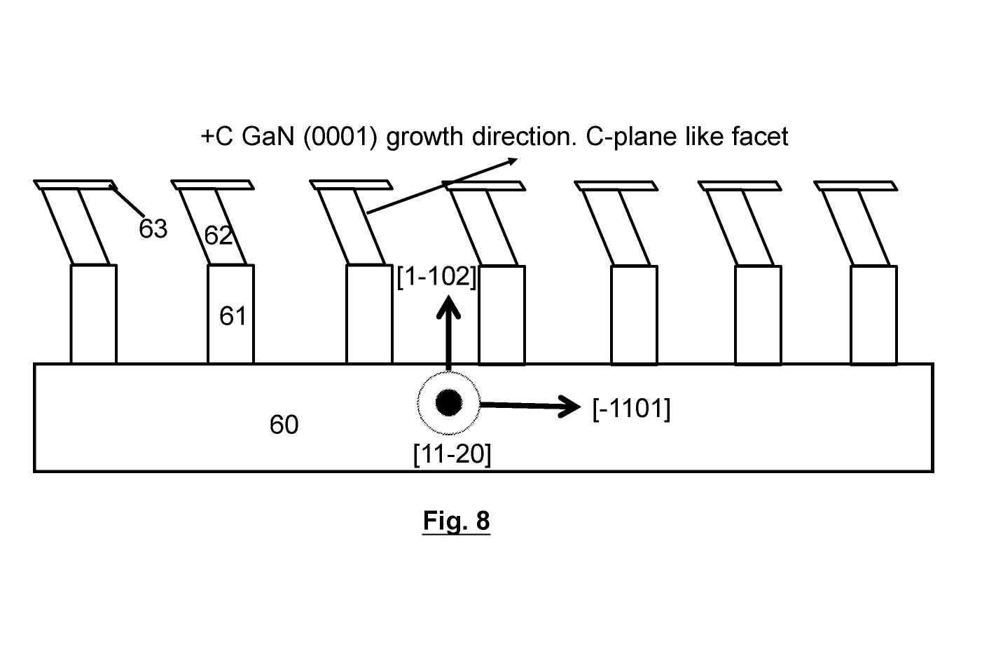

FIG. 8 schematically shows the shape of nano/micro-structures in accordance with a further embodiment of the present invention; and

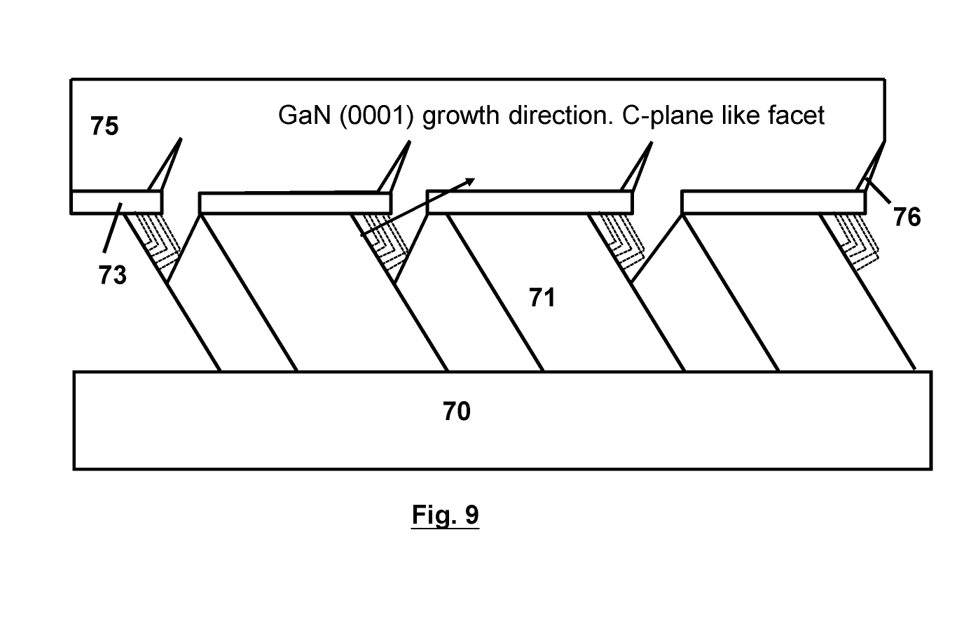

FIG. 9 schematically shows etched oblique-angled nano/micro-structures with nanometre sized air gap and micrometre sized terrace capped by the extended mask fabricated through wet etching undercut, with a semiconductor material grown thereon.

To illustrate the present invention, various practical examples using techniques in accordance with the invention are described below:

### EXAMPLE 1

A schematic drawing of the process flow of the fabrication of oblique-angle etched nano-structures and the growth of semiconductor materials on top of the oblique-angle etched nano-structures is shown in FIG. 1. In step 1, a γ-plane-oriented sapphire substrate 11 (0.8° off-axis towards c-plane) of about 2 inches (5.08 cm) in diameter has a layer 12 around 2000 nm thick of (11-22) GaN deposited thereon by MOCVD to form a template. It is then necessary to create a mask onto the template. In step 2, a thin dielectric layer 13 of SiO₂ or Si₃N₄ of ˜100 nm thickness is deposited by PECVD onto the GaN template. In step 3, the substrate is spin-coated with a UV sensitive photoresist 14, followed by a short low temperature pre-bake. The nano-imprint uses a disposable master with a striped pattern of ˜250 nm stripe. The dimension of the pitch period is about 500 nm. The air gap between the stripes is ˜250 nm. The stripe pattern is along the [10-10] GaN direction. The short UV exposure is applied during the nano-replication process. In step 4, reactive ion etching (RIE) using Ar, O₂ and CHF₃ is used to etch the photoresist 14 and dielectric materials 13, 12. After the removal of the residual photoresist, ion beam etching using a gas mixture of Ar, H₂, CHF₃, Cl₂, or BCl₃ is carried out to etch GaN materials using the dielectric nano-mask to form a high density of nano-structures. The substrate is mounted at angle of ˜58.4° towards the incoming ion beams. The depth of the etched nano-structures can be up to few micrometers to prevent GaN growth from the bottom of the grooves. The angle of the etched nano-structures is about 58.4° from the (1-102) γ-plane sapphire. The inclined sidewall facing generally upwards is the c-plane and c-plane like (001) GaN 12. Residual dielectric materials 13 are kept on top of the etched nano-structures. Further wet etching using KOH is used to fine smooth the surface of the oblique angle etched nano-stripes.

FIG. 2 shows an SEM photo of dry-etched GaN nanostructures produced in accordance with this embodiment, with the nanostructures orientated at approximately 30 degrees to the substrate plane.

In step 5 of FIG. 1, an initial epitaxial lateral overgrowth is carried out by an MOCVD growth process. The oblique-angle etched GaN nano-stripe template is loaded into the reactor. The substrate temperature is then raised to about 1000° C. with an NH₃ flow of about 2000 sccm and Trimethylgallium (TMG) flow to about 5 sccm. After about 60 minutes' growth, the TMG flow is set to about 10 sccm for about 20 minutes, then to about 20 sccm for about 30 minutes. The overgrown continuous GaN is fully coalesced within about the first 60 minutes.

The as-grown GaN template is then loaded into an HVPE reactor for bulk GaN growth. The template is heated to a temperature of about 1050° C. The pressure of the growth chamber is raised to about 300 mbar. Gas delivery to the growth chamber is set as follows for the growth process: NH₃ flow at about 3000 sccm, GaCl flow at about 120 sccm and N₂ and H₂ to make the rest of the gas. A steady total gas flow of about 6000 sccm is maintained throughout the whole growth process. The growth continues until a GaN epitaxial layer 15 of sufficient thickness is produced.

Once the substrate is cooled and removed from the reactor, the sapphire substrate can be totally or partially separated from the thick GaN epitaxial layer. A further mechanical pressure is sufficient to separate the partially separated (11-22) GaN layer 15.

### EXAMPLE 2

In this example, the process is similar to that of Example 1, except that here the template used is a simple γ-plane-oriented sapphire substrate (0.8° off-axis towards c-plane). The stripe, i.e. the length of the nano-structure, is along the [11-20] direction of the γ-plane sapphire. RIE etching using Ar, O₂ and CHF₃ is used to etch the photoresist and dielectric materials. After the removal of the residual photoresist, ion beam etching using a gas mixture of Ar, H₂, CHF₃, Cl₂, or BCl₃ is carried out to etch sapphire using the dielectric nano-mask to form a high density of elongate nano-structures (nano-stripes). Further wet etching with H₃PO₄:H₂SO₄=3:1 solution at 300° C. for 1 to 5 minutes is used to smooth the c-plane of the oblique-angle etched sapphire nano-stripes. The etched structure is ˜55.6° from the (1-102) γ-plane sapphire. The dielectric mask can be retained for the subsequent sidewall selective lateral growth. For a maskless approach on sapphire, the dielectric materials of SiO₂ or Si₃N₄ can be removed by buffered oxide etch solution and phosphoric acid respectively. The etch depth is in the range of few tens nanometres to few hundreds of nanometres. Part of the sidewalls can also be passivated by dielectrics such as silicon and metal oxides/nitrides. This passivation layer can be deposited by anisotropic film deposition method before the removal of the dielectric mask so that only the bottom part of the sidewall is passivated.

FIGS. 3a-d schematically show plan views of various different mask patterns. FIG. 3a shows a mask pattern consisting of continuous strip nano-stripes with the width of the stripes in the range from a few nm to 999 nm and the length of the stripes extending substantially across the extent of the substrate.

FIG. 3b shows a mask pattern of discrete, staggered, rectangular, relatively short stripes.

FIG. 3c shows a mask pattern of discrete, aligned, rectangular relatively short stripes.

FIG. 3d shows a pixelated mask pattern, whereby discrete groups of nano/micro-structures are formed. As shown, four groups are shown, one in each corner of the substrate, separated by a relatively wide air gap. Within each group, individual nano-/micro-structures are separated by relatively narrow air gaps.

The etched structure is 57.6° from the (1-102) γ-plane sapphire. The stripe is along the [11-20] direction of the γ-plane sapphire;

FIGS. 4a and b schematically show etched nano-stripes having nanometre-scale air gaps therebetween, the nano-stripes being etched directly onto a γ-plane sapphire substrate. In FIG. 4a, etched sapphire nano-stripes 21 are capped by dielectric mask materials 22 on the top terraces of the structures, with the underlying substrate portion being shown as 20. Through extra wet etching undercutting the sapphire, the dielectric masks 22 extend laterally from the terraces, causing an overhang. FIG. 4b is similar to FIG. 4a, but here maskless nano-stripes 31 are shown, formed on underlying substrate portion 30. The shape of the etched structure may vary due to the etching methods and materials used.

FIGS. 5a-e schematically show cross-sectional profiles of five possible shapes of the etched structure sidewalls, with the GaN (0001) growth direction marked. Other shapes are of course possible, and could, for example, comprise a combination of such shapes.

In FIG. 5a, the trench formed between the individual nano/micro-structures has an angled (i.e. not parallel to the plane of the substrate) bottom.

In FIG. 5b, nano/micro-structures are shown with substantially parallel sidewalls.

In FIG. 5c, the trench is shown as having a flat bottom, i.e. substantially parallel to the plane of the substrate.

In FIG. 5d, the trench is shown as having a sharply angled bottom, i.e. forming an acute apex.

In FIG. 5e, each nano/micro-structure has complex sidewalls having various facets inclined at different angles.

The width of the etched air gap and the width of the top terrace of the etched nano/micro-structures is preferably in the range of a few nanometres to 999 nanometres. At least one of the sidewalls comprises a c-plane or c-plane-like facet, which facilitates the fast growth of GaN (001). This sidewall faces generally upwards for easy mass transport during the subsequent epitaxy growth. At least one of these sidewalls forms an oblique angle between zero and ninety degrees relative to the plane of the surface of the substrate. An initial epitaxial lateral overgrowth is carried out by an MOCVD growth process. The oblique-angle etched sapphire nano-stripe template is loaded into the reactor. The substrate temperature is then raised to about 1050° C. for a thermal desorption under H2. Then 20 nm GaN was grown at 560° C. with V/III of 1500. The first step growth with low V/III ratio of 500, temperature 950° C., and pressure of 300 mbar is carried out for fast +c-plane GaN growth with slower lateral growth parallel to the c-plane. At the vertical +C-plane GaN thickness covers the adjacent air gap, the growth mode changes to high V/III ratio of 1500, high temperature of 1000° C., and low pressure of 200 mbar for fast lateral growth. Combined pulsed and normal growth mode will be followed for the mirror surface of the semi-polar (11-22) GaN.

### EXAMPLE 3

In this example, the process is similar to that of Example 2, except that in this case the template is a simple a-plane-orientated sapphire substrate (5° off-axis away from c-plane). The stripe is along the [10-10] direction of the a-plane sapphire. RIE etching using Ar, O₂ and CHF₃ is used to etch the photoresist and dielectric materials. After the removal of the residual photoresist, ion beam etching using a gas mixture of Ar, H₂, CHF₃, Cl₂, or BCl₃ is carried out to etch sapphire using the dielectric nano-mask to form a high density of nano-structures with an oblique angle 85° from the a-plane sapphire. Further wet etching with H₃PO₄:H₂SO₄=1:2 solution at 300° C. for 1-5 minutes is used to smooth the c-plane of the oblique angle etched sapphire nano-stripes. For a maskless approach on sapphire, the dielectric materials of SiO₂ or Si₃N₄ can be removed by buffered oxide etch solution and phosphoric acid respectively. An initial epitaxial lateral overgrowth is carried out by an MOCVD growth process. The oblique-angle etched sapphire nano-stripe template is loaded into the reactor. The substrate temperature is then raised to about 1050° C. for a thermal desorption under H2. Then 20 nm GaN is grown at 560° C. with V/III of 1500. The temperature is raised to 1010° C. for the high temperature GaN growth. The first step growth with low V/III ratio of 500, temperature of 1020° C., and pressure 350 mbar is carried out for fast +c-plane GaN growth with slower lateral growth parallel to the c-plane. At the vertical +C-plane GaN thickness covers the adjacent air gap, the growth mode changes to high V/III ratio of 1500, high temperature of 1060° C., and low pressure of 200 mbar for fast lateral growth. Combined pulsed and normal growth mode will be followed for the mirror surface of the non-polar (10-10) m-plane GaN.

### EXAMPLE 4

In this example, the process is similar to that of Example 2, except that here the template comprises (113) Si. FIG. 6 schematically shows a process flow to fabricate the nano-structures with the oblique-angle etched (1-11) and (−11-1) sidewall on Si (113). In step 1, a thin dielectric layer 42 of SiO₂ or Si₃N₄ of ˜100 nm is deposited by PECVD onto the Si template 41. In step 2, the substrate is spin-coated with a UV sensitive photoresist 43, followed by a short low temperature pre-bake. In step 3, the patterning is carried out by nano-imprint using a disposable master with the pattern of 900 nm stripe. The dimension of the pitch period is 1200 nm. The air gap is 300 nm. The stripe is along the [21-1] direction of the (113) Si. The short UV exposure is applied during the nano-replication process. In step 4, RIE etching using Ar, O₂ and CHF₃ is used to etch the photoresist and dielectric materials. After the removal of the residual photoresist, ion beam etching using a gas mixture of Ar, H₂, and CHF₃ carried out to etch Si using the dielectric nano-mask to form a high density of nano-stripes. The angle of the etched nano-stripes is about 58.4° from the (113) Si plane. Further wet etching with KOH (25 wt %) solution at 40° C. for 1-5 minutes is used to smooth the (1-11) and (−11-1) plane of the Si nano-stripes. Residual dielectric materials are kept on top of the etched nano-structures.

In step 5, an initial epitaxial lateral overgrowth is carried out by an MOCVD growth process. The oblique-angle etched Si nano-stripe template is loaded into the reactor. The substrate temperature is then raised to about 1000° C. for a thermal desorption under H2. Then 20 nm AlN is grown at 560° C. with V/III of 800. The temperature is raised to 1010° C. for the high temperature GaN growth. The first step growth with low V/III ratio of 500, temperature of 1020° C., and pressure 300 mbar is carried out for fast +c-plane GaN growth with slower lateral growth parallel to the c-plane. At the vertical +C-plane GaN thickness covers the adjacent air gap, the growth mode changes to high V/III ratio of 1500, high temperature of 1060° C., and low pressure of 200 mbar for fast lateral growth. Combined pulsed and normal growth mode is followed for the mirror surface of the semi-polar (11-22) GaN 45.

### EXAMPLE 5

Example 5 is similar to Example 2, except a full LED structure is produced after the initial (11-22) GaN bulk overgrowth. The LED structure comprises the following layers: an n-type Si-doped a-GaN layer (about 1.5-4 μm), an InGaN/GaN (20 pairs 2/2 nm) short period superlattices of thickness 80 nm, a low temperature GaN barrier of 10 nm, an InGaN/GaN MQW active region (10 pairs QWs, with the quantum well width of 2.5 nm and barrier of 12 nm), an AlGaN:Mg gradient capping layer (˜20 nm, Al concentration ramping from from 0 to 20%), and p-type Mg-doped GaN (about 0.1-0.2 μm). The electron and hole concentration in the GaN:Si and GaN:Mg layers are about 4×10¹⁸ cm⁻³ and 8×10¹⁷ cm⁻³, respectively. The LED device is then separated from the substrate to form a p-side down, thin GaN LED.

FIG. 7 schematically shows a process flow for bonding and separating LED devices from the substrate. In step 1, a series of metal and metal alloys consisting of contacting electrode/reflectors 56, buffer/diffusion barrier layers 57, and solder bonding layer 58 are fabricated on top of LED device 55 (note that in FIG. 7 the composite structure is shown upside down compared to FIG. 6 for example). The contacting electrode/reflector layers consist of Al, Ag, Ni/Ag, Ni/Au/Ag, or any good reflective metal alloys which could also form good contact with the device. The buffer/diffusion barrier layers 57 consist of Pt, Ti/W, Ti, and Ni. The bonding layers consist of In/Sn, In, Au, Au/Sn and any other suitable metal alloys. In step 2, the device 55 is then bonded at layer 58 to a thermal expansion coefficient matched submount 59, which also consists of the metal alloy bonding layers and heatsink. In step 2, the wafer bonding pressure cracks the etched nano-structures 52 and 53, and the device 55 can be separated from the substrate 51. Substrate 51 can also be removed by other mechanical methods, for example wet etching, electrochemical etching, or laser ablation.

### EXAMPLE 6

In this Example, the process is similar to that of Example 1, except that the template used is (11-22) semi-polar free standing n-GaN conducting substrate.

### EXAMPLE 8

In this Example, the process is similar to that of Example 2, except that the template used is a simple (22-43) sapphire substrate (0.45° off-axis towards c-plane). The stripe patterns are aligned perpendicular to the c-axis of (22-43) sapphire. The angle of the oblique etched structures is 74.64° from the c-plane sapphire.

### EXAMPLE 9

In this Example, the process is similar to that of Example 1, except that the thickness MOCVD-deposited (11-22) GaN is around 1000 nm. The dry etching of the GaN and sapphire is carried out by ICP using a gas mixture of Ar, H₂, Cl₂, or BCl₃. The substrate is mounted in a conventional manner so that the etched sidewall is nearly vertical related to the surface of the substrate. The depth of the etched nano-structures is exceeding 1000 nm up to 1500 nm so that the sapphire is also etched off. Further wet etching using KOH is used to create a c-plane like sidewalls of GaN for the follow on epitaxial growth. KOH etching will leave the sapphire intact. This process produces nano-structures having an angled cross-section, wherein the angle of the top part etched nano-structures is about 58.4° from the (1-102) γ-plane sapphire, while the bottom part of the etched sapphire is nearly vertical to the (1-102) sapphire. The upper, GaN, part has a slightly smaller dimension (width) compared to the lower part (sapphire) due to the extra wet etching.

FIG. 8 schematically shows such nano-structures. The inclined sidewall facing upwards is the c-plane and c-plane-like (001) GaN 62. Residual dielectric materials 63 are kept on top of the etched nano-structures. The bottom part of the etched nano-structures has nearly vertical sidewalls 61, and is the same material as the underlying substrate portion 60, i.e. sapphire.

### EXAMPLE 10

In this example, the process is similar to that of Example 4, except that here the template used has a pitch period dimension of about 5600 nm, i.e. so that the mask design employs an air gap of about 600 nm and a masked strip or terrace of about 5000 nm width. FIG. 9 schematically shows the template, with a fabricated air gap and a terrace masked by a dielectric cap. Here, etching is caused to partially remove template material underlying the mask, such that each terrace carries a region of mask that is of greater width than the respective terrace. This “undercutting” makes the air gap wider than about 600 nm with the mask 73 overhanging the strip 71, with the underlying substrate portion of the template being shown as 70. Such an extended dielectric mask can effectively block misfit dislocations and stacking faults (indicated by the dashed lines) resulting from the overgrowth of III-V nitride compound semiconductors, shown at 75. The triangular shapes 76 shown at the top right edge of each portion of mask 73 is the meeting front of two growth fronts of the III-V nitride compound semiconductors.

It will be apparent to those skilled in the art that a wide range of methods and process parameters can be accommodated within the scope of the invention, not just those explicitly described above. For example, the nano/micro-structures may be fabricated in a variety of ways, which will be apparent to those skilled in the art. The nano/micro-structures may be in the form of nano-columns, nano-pillars, and nano-stripes for example. In the case of nano-columns, these may be fabricated so as to have various shapes of sidewalls and tips, chosen as appropriate for the application in hand. The nano-columns may be fabricated in a controlled manner so as to have various predetermined patterns of nano-columns for the application in hand. The patterns can for example be photonic crystal, photonic quasicrystal, gratings, or some composite forms. Such patterns may be achieved by using a nano-imprint mask fabrication process for example. This enables the production of unique devices (e.g. LEDs, laser diodes, photovoltaic devices, microelectronics devices etc). The material of the nano/micro-structures does not have to be constant, for example the alloy content may be varied along its height in the initial layer structure of the template so that its properties are most suitable for the specific application. For example, the layers within the nano/micro-structures may consist of one layer of the material which can be selectively etched away by wet chemical, photochemical, and electrochemical etching methods. For example, the alloy content may be selected so as to optimise absorption during a laser ablation separation process. Alternatively, the layer structure of the etched nano/micro-structures can consist of the compound semiconductor and the substrate. The homo-epitaxial growth of compound semiconductor material onto the top layer of the similar compound semiconductor can be enhanced. Furthermore, the nano/micro-structure material need not be identical to that of the overgrown compound semiconductor. The grown semiconductor material using the nano/micro-structures can be used as the seed material for the further growth of high quality materials. The growth method can be CVD, MOCVD, MBE, HVPE or any other suitable methods. The process can be repeated until an optimised defects density being reached. Such semiconductor material can then be used to grow different semiconductor devices. The nano/micro-structures can be fabricated onto the semiconductor material to allow the re-cycle use of the grown semiconductor materials.

One significant alternative technique is to use a nano/micro-structures having wider terraces, with widths in the range from about 3 μm to about 15 μm, with a correspondingly wider mask cap located thereon. The air gap between these structures would preferably be smaller than 1000 nm. In this case, defects are effectively blocked by the cap, and so the requirement for fast c-plane growth is reduced. Using a ratio of 5-20:1 for the capped terrace width vs air gap significantly reduces stacking faults.

In the specific examples described, nano/micro-structures are fabricated from the template before overgrowth of the semiconductor material. However, since the use of an oblique angle etched layer permits the relatively easy removal of the semiconductor material or devices, without causing undue damage to the underlying substrates, full epitaxial devices can be grown subsequent to its removal.

1. A method of producing semiconductor material comprising the steps of:
(a) providing a base comprising a substantially planar substrate having a plurality of etched nano/micro-structures located thereon, each structure having at least one etched, substantially planar sidewall, wherein the plane of each said etched sidewall is arranged at an oblique angle to the substrate, and
(b) selectively growing the semiconductor material onto the oblique etched sidewall of each nano/micro-structure using an epitaxial growth process.

2. A method according to claim 1, wherein each nano/micro-structure is formed along an axis lying at an oblique angle to the plane of the substrate.

3. A method according to claim 1, wherein the plane of each oblique etched sidewall corresponds to the c-plane or c-plane-like plane of the substrate.

4. A method according to claim 1, wherein adjacent nano/micro-structures are separated by an air gap, the width of the air gap being the range from 1 nm to 999 nm.

5. A method according to claim 1, wherein each nano/micro-structure comprises a substantially planar terrace, substantially parallel to the plane of the substrate, and wherein the width of each terrace lies in the range from 1 nm to 999 nm.

6. (canceled)

7. A method according to claim 1, wherein each nano/micro-structure has a length in a direction parallel to the plane of the substrate which lies in the range from 1 μm to the full extent of the substrate.

8. A method according to claim 1, wherein each nano/micro-structure is dimensioned such that the ratio of the height of the structure to the width of the structure is more than 1.

9-10. (canceled)

11. A method according to claim 1, wherein the nano/micro-structures comprise a material selected from the group consisting of sapphire, SiC, ZnO, Si, metal oxides, n- or p-type doped or un-doped semiconductors, and combinations thereof.

12. A method according to claim 1, comprising the initial step of producing the nano/micro-structures.

13. A method according to claim 12, wherein the initial step comprises the step of forming a mask onto a template material, and then etching the template material to produce the nano/micro-structures.

14. A method according to claim 13, wherein the mask is removed prior to performing step (b).

15. A method according to claim 13, wherein the mask is not removed prior to performing step (b).

16. A method according to claim 15, wherein the etching is caused to partially remove template material underlying the mask, such that each terrace carries a region of mask that is of greater width than the respective terrace.

17. (canceled)

18. A method according to claim 1, wherein the substrate material comprises single crystals of different crystal orientations.

19-23. (canceled)

24. A method of producing a layered semiconductor device, comprising the steps of producing a semiconductor material using a method according to claim 1, and
(c) growing the semiconductor device onto the semiconductor material using an epitaxial growth process.

25. (canceled)

26. A method according to claim 24, comprising the step of bonding the device to a sub-mount.

27. A method according to claim 24, wherein the device is an optical device.

28. A method according to claim 27, wherein the device comprises a light emitting diode.

29. A method according to claim 27, wherein the device comprises a laser diode.

30. A method according to claim 27, wherein the device comprises a photovoltaic device.
